(19) United States
(12) Patent Application Publication
(10) Pub. No.: US 2026/0173906 A1
(43) Pub. Date: Jun. 18, 2026

(54) STACKED LOGIC AND CHIP-SCALE INTERPOSERS

(71) Applicant: International Business Machines Corporation, Armonk, NY (US)

(72) Inventors: Mukta Ghate Farooq, Hopewell Junction, NY (US); Nicholas Alexander Polomoff, Hopewell Junction, NY (US)

(21) Appl. No.: 18/982,223

(22) Filed: Dec. 16, 2024

(51) Int. Cl. H01L 23/538; G01R 31/28; H01L 23/00; H01L 23/367; H01L 25/07; H10B 80/00

(52) U.S. Cl. CPC H10W 70/611; G01R 31/2896; H10W 40/22; H10W 90/00; H10W 90/401; H10B 80/00; H10W 72/222; H10W 72/252; H10W 90/724; H10W 90/792

(57) ABSTRACT

A system-on-chip package comprises a substrate, primary chip structure, and auxiliary chip structure. The primary chip structure is structurally connected to the substrate through a set of solder balls. The auxiliary chip structure is structurally connected to the substrate through a chip-scale interposer. The primary chip structure is not structurally connected to the substrate through the chip-scale interposer.

### BACKGROUND

The present invention relates to system-on-chip (“SOC”) packages, and more specifically, to SOC packages that include primary and auxiliary chips.

Some SOC packages include both a primary chip (e.g., an SOC die) and auxiliary chips. These auxiliary chips typically provide resources (e.g., high-bandwidth memory, graphics processing) to the primary chip. In typical SOC packages, the primary and auxiliary chips are ultimately structurally connected to (e.g., mounted upon) a package substrate and covered with a lid (e.g., a heat spreader) that interfaces with the tops of the primary and auxiliary chips.

In typical SOC packages, the primary and auxiliary chips are structurally connected to the package substrate through an interposer. Specifically, the primary and auxiliary chips are typically structurally connected to the interposer (e.g., through a first ball-grid array), and the interposer is structurally connected to the package substrate (e.g., through a second ball-grid array).

### SUMMARY

Some embodiments of the present disclosure can be illustrated as a system-on-chip package. The system on chip package comprises a substrate and primary chip structure. The primary chip structure is structurally connected to the substrate through a set of solder balls. The system on chip package also comprises an auxiliary chip structure. The auxiliary chip structure is structurally connected to the substrate through a chip-scale interposer. The primary chip structure is not structurally connected to the substrate through the chip-scale interposer.

Some embodiments of the present disclosure can also be illustrated as a method. The method comprises testing a primary chip structure of a system-on-chip package. The method also comprises testing, through a chip-scale interposer, an auxiliary chip structure of the system-on-chip package. The method also comprises connecting the primary chip structure to a substrate of the system-on-chip package. The method also comprises connecting the first auxiliary chip structure to the substrate of the system-on-chip package through the chip-scale interposer.

### BRIEF DESCRIPTION OF THE DRAWINGS

FIG. 1 illustrates an SOC package that comprises a system-on-chip die that is bonded to a 3D die through a copper-copper bond.

FIG. 2 illustrates an SOC package that comprises a system-on-chip die that is electrically connected to a package substrate through copper pillars.

FIG. 3A illustrates a first stage of forming an SOC package in accordance with the embodiments of the present disclosure.

FIG. 3B illustrates a second stage of forming an SOC package in accordance with the embodiments of the present disclosure.

FIG. 3C illustrates a third stage of forming an SOC package in accordance with the embodiments of the present disclosure.

FIG. 3D illustrates a fourth stage of forming an SOC package in accordance with the embodiments of the present disclosure.

FIG. 4 illustrates an SOC package that comprises a system-on-chip die that utilizes a thick copper-copper bond.

FIG. 5 illustrates an SOC package that comprises three chip structures that are all electrically connected to a package substrate through individual chip-scale interposers.

FIG. 6 illustrates a method of testing a set of chip structures individually, according to embodiments of the present disclosure.

### DETAILED DESCRIPTION

System-on-chip (“SOC”) packages sometimes include a primary chip (e.g., an SOC die) and one or more auxiliary chips (e.g., high-bandwidth memory dies, logic dies, graphic processing dies, or other memory dies). These auxiliary chips, sometimes referred to in the industry as “active device builds” or simply “semiconductor dies” often provide resources to the primary chip that enables the entire SOC package to function more effectively. In some SOC packages, the chips (i.e., the primary chip and auxiliary chip) may be part of chip structures. For example, some primary chip structures include an SOC die and an I/O die that are stacked on top of each other. Some such primary chip structures may be referred to in the industry, for example, as a semiconductor packaged assembly build. Further, some auxiliary chip structures include several high-bandwidth memory (“HBM”) dies that are stacked on top of each other. These auxiliary chip structures may sometimes be referred to as “high-bandwidth memory stacks,” “HBM stacks,” “high-bandwidth memory die stacks,” or “HBM die stacks.”

In typical SOC packages, the primary chip structure and auxiliary chip structure(s) are structurally connected to (e.g., mounted upon) a substrate for the SOC package, and a lid (e.g., a heat spreader) is often mounted to the substrate. As described herein, the portion of the chip structures that is closest to the substrate is referred to as the “bottom” of the chip structures, and the portion of the chip structures that is farthest from the substrate is referred to as the “top” of the chip structures. In typical SOC packages, the tops of the primary chip structure and auxiliary chip structure(s) interface directly with a surface of the package lid.

In typical SOC packages, the primary and auxiliary chip structures are structurally connected to the package substrate through a package-scale interposer. This package-scale interposer has sufficient surface area for the primary and auxiliary chips to attach to, and therefore is typically significantly wider than any single primary or auxiliary chip structure in the SOC package. Further, for performance and layout reasons, the package-scale interposer is thinned significantly before the chip structures are attached (for example, to a thickness of 50 micrometers). This results in the package-scale interposer of typical SOC packages having a very thin, very wide profile.

Unfortunately, the thin, wide profile of typical package-scale interposers causes them to be susceptible to physical warping. For example, the interposer may first warp when interposer is being thinned. Further, once thinned, the interposer may warp again when the primary and auxiliary chip structures are mounted upon the interposer in a reflow process.

The tendency of package-scale interposers to warp in typical SOC packages can cause multiple performance issues. For example, the primary and auxiliary chip structures are typically structurally connected to the interposer using solder balls in a ball grid array that aligns with a set of contacts on the chip structures and a set of contacts on the interposer. When the interposer is warped, however, the distance between the individual contacts on the interposer and their corresponding contacts on the chip structures can vary. With enough variance, solder balls may become squished together, causing bridging between two sets of contacts, or may become stretched, leading to physical weakness, higher electrical resistance, and even complete lack of contact in some cases.

These issues can sometimes cause early failure rates of SOC packages or yield loss due to packages not functioning after chip joining. These consequences are compounded by the fact that a failure in the connection between a single chip structure and the interposer may cause the entire SOC package to be faulty. Further, these consequences are typically not discovered until after all chip structures are mounted upon the interposer, often resulting in the waste of all chip structures in the package, even if most chip structures are functioning properly.

Some SOC packages attempt to address these issues by structurally connecting chip structures to package-scale interposers at a larger contact pitch. In other words, some SOC packages are designed to include a larger space between solder balls in the ball grid array than would otherwise be necessary. This may reduce the risk of, for example, shorts and stretched solder balls, because arrays with larger solder balls arranged in a larger contact pitch are less susceptible to physical warping of the interposer. However, structurally connecting chip structures to the interposer at larger-than-necessary contact pitches can significantly increase the overall size of the SOC package. This increase in size increases the cost of the SOC package and places limitations on the systems into which the SOC package can be installed. Further, several chips or chip stacks (such as in HBM) may come from a supplier with a fine pitch C4 grid, which makes joining to a standard substrate almost impossible. In this case, a solution is needed which allows for a fine pitch die to be joined.

Some embodiments of the present disclosure address some of the above issues by utilizing chip-scale interposers rather than package-scale interposers. A chip-scale interposer, as used herein, refers to an interposer that is designed to be approximately the same width as the chip that is designed to be attached to it. For example, if the bottom surface of auxiliary chip structure is X mm², the surface of a chip-scale interposer to which that bottom surface is designed to attach would also be approximately X mm². These smaller interposers may be significantly less likely to warp than the package-scale interposers in typical SOC packages, which can mitigate the resulting yield and failure issues discussed above.

Further, by incorporating chip-scale interposers, the SOC packages of the present disclosure are more flexible in the manner in which the chip structures can be attached to the package substrates. For example, a primary chip structure may be connected to the package substrate at a different pitch than the auxiliary chip structure(s) in an SOC package. In some embodiments, for example, an SOC die in a primary chip structure may be connected to the package substrate through another die (e.g., an I/O die) or through a set of conductive pillars (e.g., copper pillars), which may be structurally connected to the substrate. Further, using chip-scale interposers of different thicknesses can enable the SOC package to incorporate auxiliary chip structures of different thicknesses while still causing the top surfaces of all chip structures to interface with a package lid.

Finally, attaching chip structures to a package substrate separately (e.g., with separate chip-scale interposers) may enable testing of each chip structure individually before it is connected to the package substrate. This may increase overall yields of SOC packages by identifying failed chip structures before they are connected to the SOC package.

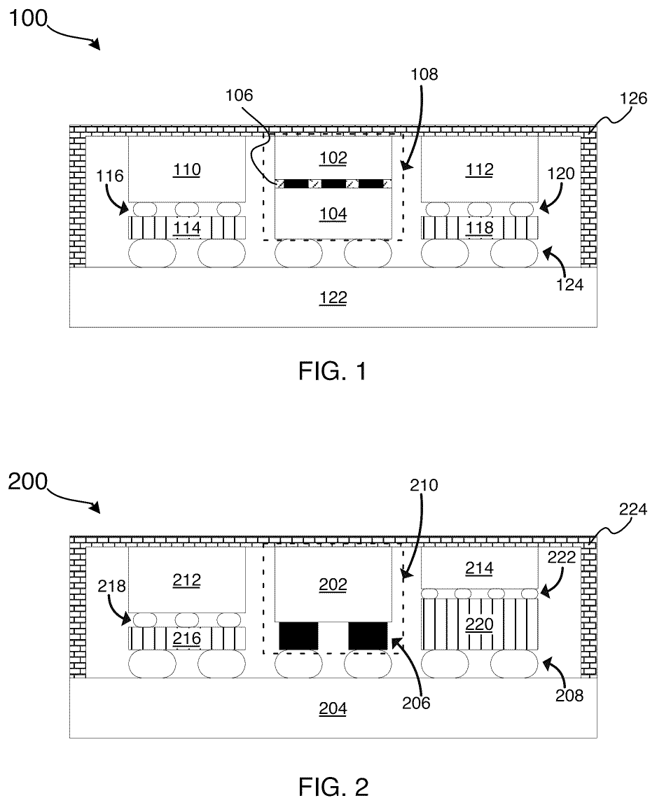

FIG. 1 illustrates SOC package 100 that includes system-on-chip (“SOC”) die 102 that is bonded to 3D die 104 through copper-copper bond 106. Copper-copper bond 106 is a type of copper-hybrid bond, also sometimes referred to as a copper-hybrid interconnect. While SOC package 100 and other embodiments of this disclosure are described using the term “copper-copper bond,” those of skill in the art understand that other copper-hybrid bonds may be used in some embodiments. SOC die 102, 3D die 104, and copper-copper bond 106 together form primary chip structure 108, which is roughly denoted in FIG. 1 by a dashed line.

3D dies, such as 3D die 104, typically contain through silicon vias and added functionality that can be utilized by other dies, such as SOC die 102. 3D die 104, for example, may contain an integrated voltage regulator, stacked capacitors, deep trench capacitors, one or more inductors, and/or an I/O function.

SOC package 100 also includes a first auxiliary chip structure 110 and a second auxiliary chip structure 112. First auxiliary chip structure 110 is structurally connected to chip-scale interposer 114 through solder-ball grid 116. Second auxiliary chip structure 112 is structurally connected to chip-scale interposer 118 through solder-ball grid 120. Primary chip structure 108, chip-scale interposer 114, and chip-scale interposer 118 are structurally connected to package substrate 122 through solder-ball grid 124.

Finally, SOC package 100 contains package lid 126. Package lid 126 may take the form of a metallic heat spreader that serves as a thermal interface between a heat sink and primary chip structure 108, first auxiliary chip structure 110, and second auxiliary chip structure 112. As such, performance of SOC package 100 may be significantly improved if the top surfaces of primary chip structure 108, first auxiliary chip structure 110, and second auxiliary chip structure 112 all interface with package lid 126. For this reason, it may be particularly important for the top surfaces of primary chip structure 108, first auxiliary chip structure 110, and second auxiliary chip structure 112 to be in the same horizontal plane (as illustrated in FIG. 1). In other words, the top surfaces of primary chip structure 108, first auxiliary chip structure 110, and second auxiliary chip structure 112 may all be in the same horizontal plane that is itself parallel to the top surface of package substrate 122.

As used herein, a connection between two or more components can be described as “structural” or “electrical” and as “direct” or “indirect.” A first component is described as structurally connected to a second component if there is a continuous physical/mechanical connection or series of connections (e.g., a series of solder-ball and hybrid-bond connections) between the first and second components. Further, a first component may be described as structurally connected to a second component through a third component if that first component and second component rely upon the third component, directly or indirectly, for primary structural connection structural connection between the first and second component.

For example, second auxiliary chip structure 110 may be described as connected to package substrate 122, structurally connected to package substrate 122, and indirectly structurally connected to package substrate 122. However, second auxiliary chip structure 112 would not be described as directly structurally connected to package substrate 122. Rather, second auxiliary chip structure 112 could be described as directly structurally connected to solder-ball grid 120.

Further, second auxiliary chip structure 112 could be described as structurally connected to package substrate 122 through solder ball grid 120, chip-scale interposer 118, and solder-ball grid 124 because second auxiliary chip structure 112 relies upon solder ball grid 120, chip-scale interposer 118, and solder-ball grid 124 for its primary structural connection to package substrate 122. Specifically, second auxiliary chip structure 112 could be described as connected to package substrate 122 though all those components collectively, or individually. In other words, second auxiliary chip structure 112 could be described as being structurally connected (or indirectly structurally connected) to package substrate 122 through chip-scale interposer 118, despite the fact that second auxiliary chip structure 112 is not directly structurally connected to chip-scale interposer 118.

However, despite the fact that a continuous physical connection exists between, for example, second chip structure 112 and package substrate 122 though package lid 126, first auxiliary chip structure 110, solder-ball grid 116, chip-scale interposer 114, and solder-ball grid 124, second chip structure 112 would not be described as structurally connected to package substrate 122 through, for example, chip-scale interposer 114 because second chip structure 112 does not rely upon chip-scale interposer 114 for its primary structural connection to package substrate 122.

Finally, second auxiliary chip structure 112 could be described as electrically connected to package substrate 122 if an electrical path (e.g., wires, contacts, solder balls) is designed to connect second auxiliary chip structure 112 to package substrate 122. For example, an electrical connection could follow a path from second auxiliary chip structure 112, through one or more of the solder balls in solder-ball grid 120, through chip-scale interposer 118, and through one or more of solder balls in solder-ball grid 124. In that example, second auxiliary chip structure 112 could be described as electrically connected to all of, or individually any of, solder-ball grid 120, chip scale interposer 118, and solder-ball grid 124. Further, if that path followed a trace from solder-ball grid 124, through package substrate 122, back through solder ball grid 124, into 3D die 104, back through solder ball grid 124 again, and into package substrate 122 again, second auxiliary chip structure 112 could also be described as electrically connected to package substrate 122 through 3D die 104.

First auxiliary chip structure 110 and second auxiliary chip structure 112 may take various forms, such as logic dies, HBM dies (e.g., HBM die stacks), of graphics processing dies. In some embodiments, first auxiliary chip structure 110 and second auxiliary chip structure 112 may take the form of a stack of dies. Further, first auxiliary chip structure 110 and second auxiliary chip structure 112 may be of varying thicknesses, such as equal to a standard die thickness, thinner than a standard die thickness, or thicker than a standard die thickness. While in FIG. 1, first auxiliary chip structure 110 and second auxiliary chip structure 112 are illustrated as equally thick, in some embodiments of the present disclosure an SOC package may utilize auxiliary chip structures that are of different thicknesses.

Copper-copper bond 106 is composed of copper contact pads encased in dielectric (e.g., an oxide). The controllable nature of copper-hybrid bonding can be utilized to precisely control the thickness of copper-copper bond 106 to even a single micron, in some methods. For this reason, the thickness of copper-copper bond 106 can be manipulated to adjust the overall thickness of primary chip structure 108. For example, if one or both of first auxiliary chip structure 110 and second auxiliary chip structure 112 were thicker than a standard die thickness, package lid 126 may be higher than shown in FIG. 1. In this example, copper-copper bond 106 could be designed to be thicker in an attempt to cause the top surface of SOC die 102 to interface with package lid 126 at that higher level.

Of note, primary chip structure 108 is not shown to be structurally connected to package substrate 122 through an interposer. This may be because, for example, the wiring and internal functions of 3D die 104 may enable it to bond to a solder-ball grid that has a wide pitch, such as solder-ball grid 124. Thus, in SOC package 100, primary chip structure 108 may be described as structurally connected to package substrate through a set of solder balls (solder-ball grid 124). Further, primary chip structure 108 may be described as electrically connected to package substrate 122 through solder-ball grid 124. In some other embodiments of the present disclosure, a primary chip structure may be structurally connected to a substrate through a chip-scale interposer. Such an embodiment is discussed with respect to FIG. 5.

As noted previously, utilizing chip-scale interposers in an SOC package can enable significant flexibility in design for the components that are integrated into the SOC package. This added flexibility is in addition to the reliability benefits that step from avoiding a higher likelihood of warpage that is present in SOC packages that utilize package-scale interposers.

For example, FIG. 2 illustrates SOC package 200 that comprises system-on-chip (“SOC”) die 202 that is structurally connected to package substrate 204 through copper pillars 206 and solder-ball grid 208. SOC die 202 and copper pillars 206 together form primary chip structure 210, which can also be described as structurally connected to package substrate 204 through solder-ball grid 208.

Like SOC package 100, SOC package 200 includes first auxiliary chip structure 212 and second auxiliary die structure 214. First auxiliary chip structure 212 is structurally connected to chip-scale interposer 216 though solder-ball grid 218. Second auxiliary chip structure 214 is structurally connected to chip-scale interposer 220 though solder-ball grid 222.

As illustrated, first auxiliary chip structure 212 is significantly thicker than second auxiliary chip structure 214. However, because SOC package 200 utilizes chip-scale interposers rather than package-scale interposers, this significant difference of thickness can be easily accounted for. Specifically, as illustrated, chip-scale interposer 220 is significantly thicker than chip-scale interposer 216. As a result, the total thickness of first auxiliary chip structure 212, chip-scale interposer 216, and solder-ball grid 218 is equal to the total thickness of second auxiliary chip structure 214, chip-scale interposer 220, and solder-ball grid 222. This may enable the top surfaces of both first auxiliary chip structure 212 and second auxiliary chip structure 214 to interface with package lid 224.

Further, solder-ball grid 222 is illustrated as being composed of smaller solder balls organized in a smaller grid pitch than those of solder-ball grid 218. This may be because, for example, second auxiliary chip structure 214 has more contact pads than first auxiliary chip structure 212, and thus requires more connections to chip-scale interposer 220. Because SOC package 200 utilizes two chip-scale interposers rather than a single package-scale interposer, this difference can be accounted for by designing chip-scale interposer with contacts to match the pitch and number of solder-ball grid 222 rather than that of solder-ball grid 218. This may increase the flexibility with which SOC package 200 may be designed. In other words, auxiliary packages that require solder-ball grids with smaller pitches can be incorporated while avoiding the warping that may cause shorts or gaps in those solder-ball grids in an SOC package that utilizes package-scale interposers.

As noted above, utilizing chip-scale interposers in an SOC package can also prevent unnecessary yield loss of entire SOC packages due to faulty components. Specifically, when utilizing chip-scale interposers, each component can be tested individually through their connection to the package substrate before they are actually attached to the substrate. If, for example, an auxiliary chip structure (e.g., an HBM memory stack) is tested through its chip-scale interposer before being structurally connected (e.g., mounted) to the package substrate, it can be disposed of individually before it is structurally connected to the substrate. This prevents the loss of the other, functioning chip structures (e.g., an SOC die) that are already structurally connected (e.g., mounted) to the substrate.

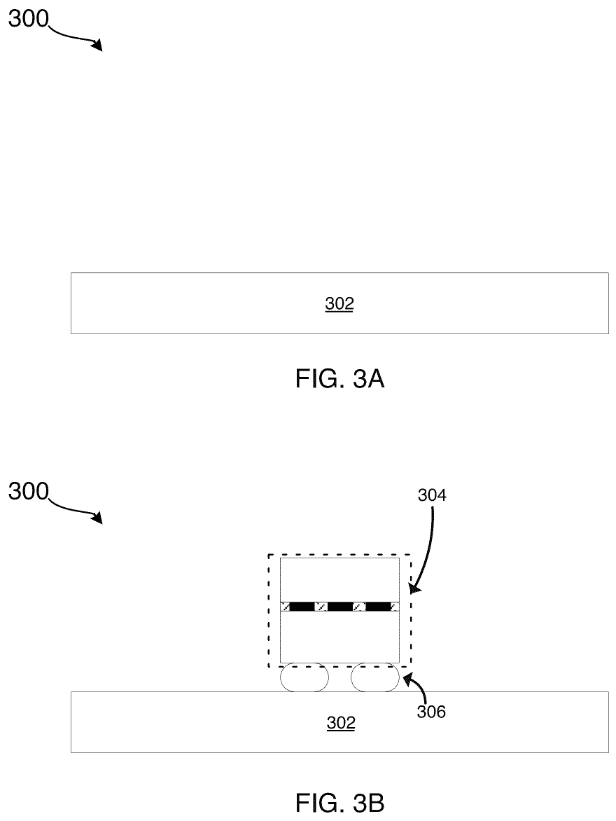

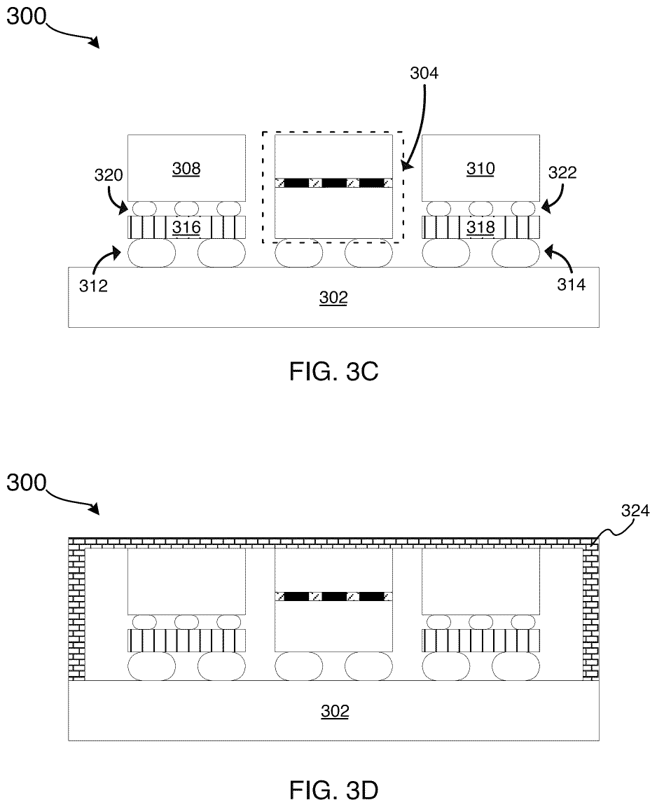

FIGS. 3A-3D, for example, present one possible method of assembling an SOC package 300 that can take advantage of this individual testing.

FIG. 3A illustrates a first stage of forming SOC package 300. In this first stage, package substrate 302 has been formed, but no chip structures have been mounted to the substrate.

FIG. 3B illustrates a second stage of forming SOC package 300. In FIG. 3B, primary chip structure 304 has been structurally connected to package substrate 302 through solder-ball grid 306. Primary chip structure 304 may take the form of an SOC die that is bonded to a 3D die through a copper-copper bond. The 3D die may provide some functionality to the SOC die, such as voltage regulation.

Because primary chip structure 304 is electrically connected to substrate 302 through the relatively larger pitch of solder-ball grid 306 (e.g., 150 micrometer pitch), testing primary chip structure 304 before structurally connecting primary chip structure 304 to substrate 302 should be feasible. This testing can occur in a wafer level format where the entire wafer containing dies 104 is attached to the entire wafer containing dies 102, or the individual dies 102 are attached to the entire wafer 104 using a die to wafer joining method. This is followed by testing of the wafer containing stacks of die 102 on die 104, by probing the large C4s 306. By doing so, it may be possible to avoid fully assembling SOC package 300 only to realize that the SOC die is malfunctioning, causing the entire SOC package to be wasted.

Similarly, FIG. 3C illustrates a third stage of forming SOC package 300. In FIG. 3C, auxiliary chip structures 308 and 310 have been structurally connected to substrate 302 through solder-ball grids 312 and 314. More specifically, however, auxiliary chip structures 308 and 310 have been indirectly structurally connected to chip-scale interposers 316 and 318 through direct structural connections to solder-ball grids 320 and 322.

Because of the relatively small pitch by which auxiliary chip structures 308 and 310 are attached to chip-scale interposers 316 and 318 (i.e., the pitch of solder-ball grids 320 and 322), testing auxiliary chip structures 308 and 310 before structurally connecting them to chip-scale interposers 316 and 318 may be unfeasible, or at least more difficult and time consuming. However, after structurally connecting to chip-scale interposers 316 and 318, which connect with the relatively larger pitch of solder-ball grids 312 and 314, both auxiliary chip structures 308 and 310 can be tested individually. In other words, again, utilizing chip-scale interposers may avoid realizing after fully assembling SOC package 300 that one of the components of SOC package 300 is faulty. If, on the other hand, SOC package 300 utilized a package-scale interposer, testing primary chip structure 304 and auxiliary chip structures 308 and 310 may only be feasible after those structures were structurally connected to the package-scale interposer. Even if each structure were mounted to the package-scale interposer individually and tested after being mounted, the entire SOC package may be wasted if the final chip structure that is mounted is tested to be faulty after it is attached.

Finally, FIG. 3D illustrates a fourth stage of forming SOC package 300. In this fourth stage, package lid 324 is attached to substrate 302. Package lid 324 can then provide a thermal interface between the chip structures within SOC package 300 and a system heat sink, for example.

As has been discussed previously, utilizing chip-scale interposers in some chip structures in an SOC package can also enable other structural connection methods (e.g., mounting methods) for other chip structures in the SOC package. For example, in some embodiments discussed above, an SOC die may be structurally connected to a package substrate through a 3D die rather than an interposer. In these examples, the SOC die may be structurally connected to the 3D die with a copper-copper bond. These example embodiments may also benefit from the precise controllability of copper-hybrid bonding.

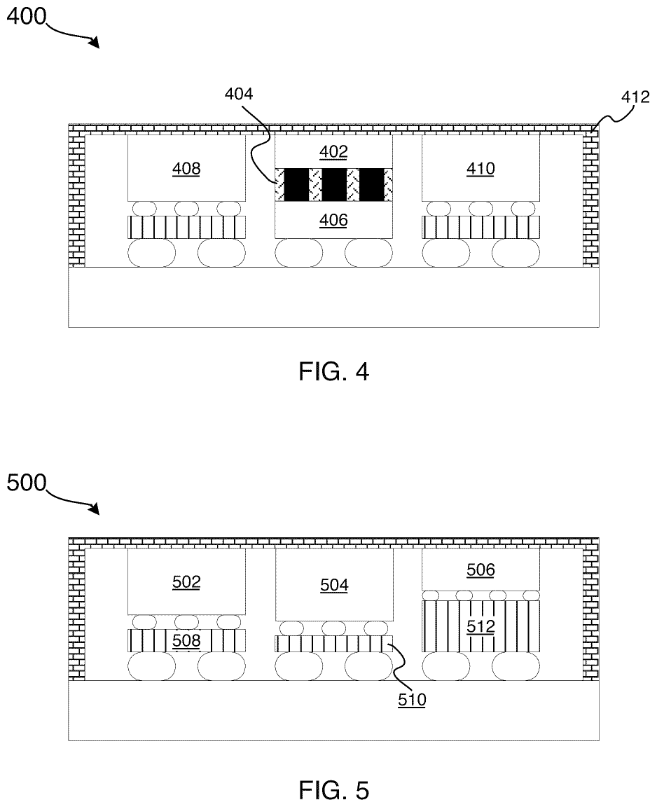

For example FIG. 4 illustrates SOC package 400 that includes system-on-chip die 402 that utilizes a thick copper-copper bond 404 to connect with 3D die 406. A thick copper-copper bond interface may be beneficial, for example, if auxiliary chip structures 408 and 410 were of a high-than standard thickness, a thin copper-copper bond between SOC die 402 and 3D die 406 may prevent SOC die 402 from interfacing with package lid 412. However, by precisely controlling the thickness of copper-copper bond 404 to account for the extra height of auxiliary chip structures 408 and 410, all of SOC die 402, auxiliary chip structure 408, and auxiliary chip structure 410 may all interface with package lid 412.

As has also been discussed previously, the incorporation of chip-scale interposers by itself can also lead to flexibilities in designs of SOC packages, even if copper-hybrid bonding or copper pillars are not used to connect chip structures to the package substrate.

For example, FIG. 5 illustrates an SOC package 500 that includes three chip structures 502, 504, and 506 that are all structurally connected to a package substrate by individual chip scale interposers 508, 510, and 512. One or more of chip structures 502, 504, and 506 may be a primary chip structure, and one or more of the remaining chip structures may be an auxiliary chip structure (i.e., a chip structure that provides extra functionality/resources to the primary chip structure). For example, chip structures 502 and 504 may be SOC dies, and chip structure 506 may be a GPU processor that provides graphics-processing capabilities to chip structures 502 and 504.

As illustrated in FIG. 5, chip structures 502, 504, and 506 all have different thicknesses, and chip structure 506 has a smaller pitch at which it is connected to its chip-scale interposer (chip-scale interposer 512) than chip structures 502 and 504. However, because each of chip-scale interposers 508, 510, and 512 can be designed for its corresponding chip structure, these differences can be accommodated. For example, chip-scale interposer 510 is slightly thinner than chip-scale interposer 508, because chip structure 504 is slightly thicker than chip structure 502. Further, chip-scale interposer 512 is significantly thicker than chip-scale interposers 508 and 510 because chip structure 506 is significantly thinner than chip structures 502 and 504 and because the solder balls that connect chip structure 506 to chip-scale interposer 512 are smaller than the solder balls that connect chip structures 502 and 504 to their corresponding chip-scale interposers.

As noted earlier, one or more of chip structures 502, 504, 506 may be a primary chip structure. For example, chip structure 506 may be a primary chip structure, such as a SOC die. In such an example, chip structure 506 could be described as a primary chip structure that is connected (structurally connected and electrically connected) to a package substrate through a chip-scale interposer.

As noted with respect to FIG. 3A-3D, utilizing chip-scale interposers in an SOC package can enable individually testing each chip structure through their connection to the package substrate before they are actually attached to the substrate. This can result in determining that a chip structure is faulty prior to connecting that chip structure to the substrate. Such a faulty chip structure could then be disposed prior to connecting the chip structure to the substrate, preventing the need to also dispose of all other chip structures on the substrate as well.

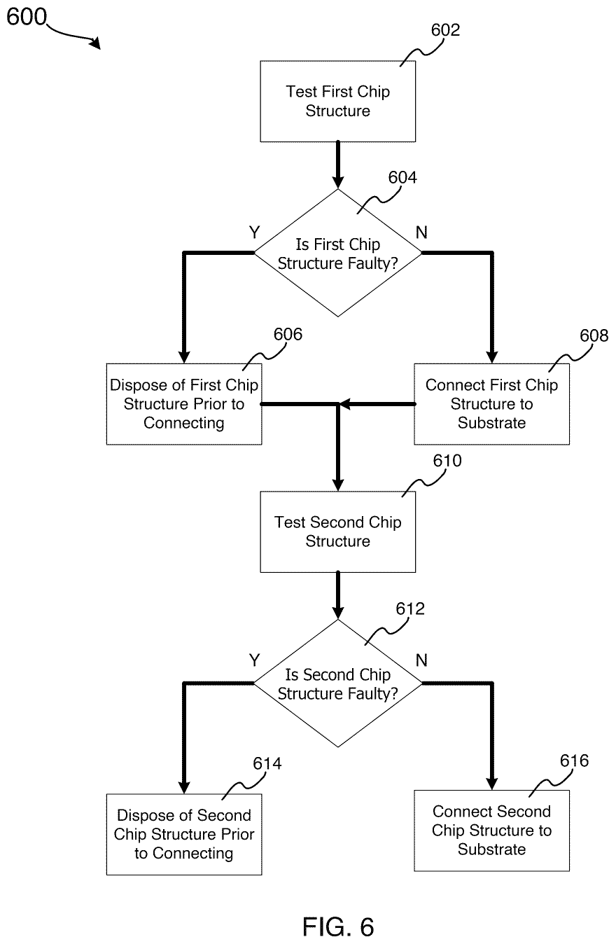

FIG. 6 illustrates a method 600 of testing a set of chip structures individually, according to embodiments of the present disclosure. Method 600 begins in block 602, in which a first chip structure is tested. This chip structure may be, for example, a primary chip structure or an auxiliary chip structure. Thus, block 602 may include testing an auxiliary chip structure through a chip-scale interposer. Block 602 could also include directly testing a primary chip structure not through a chip-scale interposer (e.g., through a set of contact pads upon the primary chip structure or through a set of copper pillars on the primary chip structure). In typical embodiments, the first chip structure will be tested in block 602 prior to being connected to the substrate.

Method 600 continues in block 604, in which it is determined whether the first chip structure is faulty. If the first chip structure is determined to be faulty, method 600 proceeds to block 606, in which the first chip structure is disposed of prior to connecting the first chip structure to the substrate.

As used herein, the phrase “prior to,” as in “prior to connecting the chip structure to the substrate” may refer to performing one step (here, disposing of the first chip structure) before performing a second step even if that second step is never performed. For example, in the case of block 606, the first chip structure that is disposed of will likely never be connected to the substrate.

However, the phrase “prior to,” as used herein, may also refer to performing one step before performing a second step when that second step is likely to be, or eventually is, performed. For example, the phrase “testing a first chip structure prior to testing a second chip structure” may be used to describe a situation in which a first chip structure is tested, after which a second chip structure is tested. Similarly, the phrase “testing a chip structure prior to structurally connecting the chip structure to a substrate” may be used to describe a situation in which a chip structure is tested, after which the chip structure is structurally connected to a substrate.

If the first chip structure is not determined to be faulty, method 600 proceeds from block 604 to block 608. In block 608, the first chip structure is connected to the substrate.

After either of blocks 606 and 608, method 600 proceeds to block 610, in which a second chip structure is tested. Block 610 may resemble block 602. For example, the second chip structure may be a primary chip structure or secondary chip structure. After block 610, method 600 proceeds to block 612, in which it is determined whether the second chip structure is faulty. If the second chip structure is determined to be faulty, method 600 proceeds to block 614, in which the second chip structure is disposed of prior to being connected to the substrate. If, on the other hand, the second chip structure is not found to be faulty, method 600 proceeds from block 612 to block 616, in which the second chip structure is connected to the substrate.

While, as described, method 600 follows a chronological order, some steps of method 600 could occur in an order other than the order described. For example, in some embodiments some or all connections to the substrate may be made at the same time. In those embodiments, chip structures may be individually tested, faulty chip structures may be disposed of, and then non-faulty chip structures may be simultaneously connected to the substrate. For example, in these embodiments, blocks 608 and 616 may occur simultaneously at the end of method 600. In other embodiments, some or all chip structures may be tested simultaneously, though prior to being connected to the substrate and individually. In these embodiments, blocks 602 and 610 may occur simultaneously at the beginning of method 600.

As described above, some embodiments of the present disclosure may take the form of a system-on-chip package. The system-on-chip package comprises a substrate. The system-on-chip package also comprises a primary chip structure. The primary chip structure is structurally connected to the substrate through a set of solder balls. The system-on-chip package also comprises a first auxiliary chip structure. The first auxiliary chip structure is structurally connected to the substrate through a first chip-scale interposer. The primary chip structure in the system-on-chip package is not structurally connected to the substrate through the chip-scale interposer. An advantage of these embodiments is the ability to independently test the primary chip structure and the auxiliary chip structure before connecting them to the substrate. A further advantage of these embodiments is lower warpage strain on the system-on-chip package during reflow.

In a first particular embodiment of the above system-on-chip package, the primary chip structure comprises a system-on-chip die and a 3D die. The 3D die is bonded to the system-on-chip die through a copper-hybrid bond. An advantage of this particular embodiment is low latency between the system-on-chip die and 3D die.

In a second particular embodiment of the above first particular embodiment, the 3D die is an input-output die. An advantage of this particular embodiment is low latency between input-output functions and the system-on-chip die.

In a third particular embodiment of the above system-on-chip package, the primary chip structure comprises a system-on-chip die and a set of copper pillars. The set of copper pillars connect the system-on-chip die to the set of solder balls. An advantage of this embodiment is a higher copper-to-solder ratio in the connection between the system-on-chip die and the substrate, which provides electromigration resistance.

In a fourth particular embodiment of the above system-on-chip package, the primary chip structure comprises a system-on-chip die and a second chip-scale interposer. An advantage of this particular embodiment is the ability to incorporate chip-scale interposers of unique properties for each chip structure.

In a fifth particular embodiment of the above system-on-chip package, the system-on-chip package comprises a head-spreader lid that interfaces with the primary chip structure and the first auxiliary chip structure. An advantage of this particular embodiment is increased thermal performance.

In a sixth particular embodiment of the above system-on-chip package, the first auxiliary chip structure is a high-bandwidth memory die stack. An advantage of this particular embodiment is the ability to test a high-bandwidth memory die stack before it is connected to the substrate.

In a seventh particular embodiment of the above system-on-chip package, the first auxiliary chip structure is a graphics processing unit die. An advantage of this particular embodiment is the ability to test a graphics processing unit die before it is connected to the substrate.

In an eighth particular embodiment of the above system-on-chip package, the system-on-chip package further comprises a second auxiliary chip structure that is structurally connected to the substrate through a second chip-scale interposer. An advantage of this particular embodiment is the ability to incorporate chip-scale interposers of unique properties for each chip structure.

In a ninth particular embodiment of the above system-on-chip package, the first chip-scale interposer is the same approximate width as the first auxiliary chip structure. An advantage of this particular embodiment is the prevention of unnecessary space being occupied by the chip-scale interposer.

A person of skill in the art would understand that combinations of some of the above nine particular embodiments of the system-on-chip package, as discussed elsewhere in this application, may be possible and may provide further advantages.

As described above, some embodiments of the present disclosure may take the form of a method. The method comprises testing a primary chip structure of a system-on-chip package. The method further comprises testing, through a first chip-scale interposer, a first auxiliary chip structure of the system-on-chip package. The method further comprises connecting the primary chip structure to a substrate of the system-on-chip package. The method further comprises connecting the first auxiliary chip structure to the substrate of the system-on-chip package through the first chip-scale interposer. An advantage of this method is the ability to independently test the primary chip structure and auxiliary chip structure before connecting them to the substrate.

In a first particular embodiment of the above method, testing the primary chip structure comprises testing the primary chip structure through a set of contact pads on the primary chip structure. An advantage of this embodiment is the ability to easily test the primary chip structure without attaching the primary chip structure to a substrate.

In a second particular embodiment of the above method, testing the primary chip structure comprises testing the primary chip structure through a set of copper pillars on the primary chip structure. An advantage of this embodiment is the ability to easily test the primary chip structure without attaching the primary chip structure to a substrate.

In a third particular embodiment of the above method, testing the first auxiliary chip structure occurs after connecting the primary chip structure to the substrate. An advantage of this embodiment is the ability to test the auxiliary chip structure and to connect the primary chip structure to the substrate independently.

In a fourth particular embodiment of the above method, testing the primary chip structure occurs after connecting the first auxiliary chip structure to the substrate. An advantage of this embodiment is the ability to test the primary chip structure and to connect the auxiliary chip structure to the substrate independently.

In a fifth particular embodiment of the above method, the method further comprises testing through a second chip-scale interposer, a second auxiliary chip structure. The method further comprises connecting the second auxiliary chip structure to the substrate through the second chip-scale interposer. An advantage of this embodiment is the ability to independently test the primary chip structure, first auxiliary chip structure, and second auxiliary chip structure before connecting them to the substrate.

In a sixth particular embodiment of the above method, the method further comprises testing, through a second chip-scale interposer, a second auxiliary chip structure. The method further comprises determining that the second auxiliary chip structure is faulty. The method further comprises disposing the second auxiliary chip structure prior to connecting the second auxiliary chip structure to the substrate. An advantage of this embodiment is avoiding a faulty chip structure from necessitating the disposal of the primary chip structure and first auxiliary chip structure.

A person of skill in the art would understand that combinations of some of the above six particular embodiments of the above method, as discussed elsewhere in this application, may be possible and may provide further advantages.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system-on-chip package comprising:
a substrate;
a primary chip structure that is structurally connected to the substrate through a set of solder balls; and
a first auxiliary chip structure that is structurally connected to the substrate through a first chip-scale interposer;
wherein the primary chip structure is not structurally connected to the substrate through the first chip-scale interposer.

2. The system-on-chip package of claim 1, wherein the primary chip structure comprises:
a system-on-chip die; and
a 3D die bonded to the system-on-chip die through a copper-hybrid bond.

3. The system-on-chip package of claim 2, wherein the 3D die is an input-output die.

4. The system-on-chip package of claim 1, wherein the primary chip structure comprises:
a system-on-chip die; and
a set of copper pillars that connect the system-on-chip die to the set of solder balls.

5. The system-on-chip package of claim 1, wherein the primary chip structure comprises:
a system-on-chip die; and
a second chip-scale interposer.

6. The system-on-chip package of claim 1, further comprising a head-spreader lid that interfaces with the primary chip structure and the first auxiliary chip structure.

7. The system-on-chip package of claim 1, wherein the first auxiliary chip structure is a high-bandwidth memory die stack.

8. The system-on-chip package of claim 1, wherein the first auxiliary chip structure is a graphics processing unit die.

9. The system-on-chip package of claim 1, further comprising:
a second auxiliary chip structure that is structurally connected to the substrate through a second chip-scale interposer.

10. The system-on-chip package of claim 1, wherein the first chip-scale interposer is the same approximate width as the first auxiliary chip structure.

11. A method comprising:
testing a primary chip structure of a system-on-chip package;
testing, through a first chip-scale interposer, a first auxiliary chip structure of the system-on-chip package;
connecting the primary chip structure to a substrate of the system-on-chip package; and
connecting the first auxiliary chip structure to the substrate of the system-on-chip package through the first chip-scale interposer.

12. The method of claim 11, wherein the testing the primary chip structure comprises testing the primary chip structure through a set of contact pads on the primary chip structure.

13. The method of claim 11, wherein the testing the primary chip structure comprises testing the primary chip structure through a set of copper pillars.

14. The method of claim 11, wherein the testing the first auxiliary chip structure occurs after the connecting the primary chip structure to the substrate.

15. The method of claim 11, wherein the testing the primary chip structure occurs after the connecting the first auxiliary chip structure to the substrate.

16. The method of claim 11, further comprising:
testing, through a second chip-scale interposer, a second auxiliary chip structure; and
connecting the second auxiliary chip structure to the substrate through the second chip-scale interposer.

17. The method of claim 11, further comprising:
testing, through a second chip-scale interposer, a second auxiliary chip structure;
determining, based on the testing the second auxiliary chip structure, that the second auxiliary chip structure is faulty; and
disposing, in response to the determining, the second auxiliary chip structure prior to connecting the second auxiliary chip structure to the substrate.
